(19) United States
(12) Patent Application Publication
(10) Pub. No.: US 2026/0155183 A1
(43) Pub. Date: Jun. 4, 2026

(54) MEMORY DEVICE HAVING ENHANCED DATA RELIABILITY, MEMORY SYSTEM INCLUDING THE MEMORY DEVICE, AND OPERATING METHOD OF THE MEMORY DEVICE

(71) Applicant: Samsung Electronics Co., Ltd., Suwon-si (KR)

(72) Inventors: Jongdae Hwang, Suwon-si (KR); Kwangho Choi, Suwon-si (KR); Sangbeen You, Suwon-si (KR); Yonghyuk Choi, Suwon-si (KR)

(21) Appl. No.: 19/382,768

(22) Filed: Nov. 7, 2025

(30) Foreign Application Priority Data
Dec. 3, 2024 (KR) 10-2024-0177723

(51) Int. Cl. G11C 16/10

(52) U.S. Cl. CPC G11C 16/10

(57) ABSTRACT

A memory device includes a memory cell array including a plurality of cell blocks having a plurality of cell strings, and a control logic circuit configured to control a program operation on the memory cell array, in which the plurality of cell blocks includes a plurality of main word lines arranged vertically and configured to be programmed with data, a GSL region including a plurality of ground selection lines coded to be electrically separated on the plurality of cell strings, and at least one common GSL disposed in common on the plurality of cell strings, and the control logic circuit is configured to perform a control operation to cut off at least one ground selection line included in the GSL region upon upper word lines of the plurality of main word lines being programmed and cut off the at least one common GSL upon lower word lines being programmed.

### CROSS-REFERENCE TO RELATED APPLICATION

This application claims priority to Korean Patent Application No. 10-2024-0177723, filed in the Korean Intellectual Property Office on Dec. 3, 2024, the disclosure of which is incorporated by reference herein in its entirety.

### BACKGROUND

Non-volatile memory devices are a type of memory device and include a plurality of memory cells which store data in a non-volatile manner. As an example of non-volatile memory devices, flash memory devices may be used in portable phones, digital cameras, portable digital assistants (PDA), mobile computer devices, stationary computer devices, servers, and various other systems.

Three-dimensional (3D) memory devices including a plurality of vertical channel structures extending in a vertical direction on a substrate have been developed to increase the capacity of memory devices. Each cell block of 3D memory devices may include a plurality of cell strings, and ground selection lines on the plurality of cell strings are separated from each other in association with a memory operation. To enhance the degree of integration of memory devices, as a dummy hole is formed in a memory device, a ground selection line (GSL) region including a plurality of ground selection lines (for example, coding GSLs) coded to have a certain threshold voltage may be provided instead of physically separating ground selection lines, and thus, ground selection lines are electrically separated on a plurality of cell strings.

However, as the degree of integration of memory devices increases, a degradation in characteristics caused by hot carrier injection (HCI) may occur in ground selection lines included in a GSL region, and this may be a cause of a reduction in data reliability of memory devices.

### SUMMARY

In general, the present disclosure is directed toward a memory device that may prevent a reduction in characteristic of ground selection lines included in a ground selection line (GSL) region and may enhance the reliability of data, a memory system including the memory device, and an operating method of the memory device.

According to some implementations, the present disclosure is directed to a memory device that includes a memory cell array including a plurality of cell blocks each including a plurality of cell strings and a control logic configured to control a program operation on the memory cell array, wherein each of the plurality of cell blocks includes a plurality of main word lines arranged vertically and programmed with data, a ground selection line (GSL) region including a plurality of ground selection lines coded to be electrically separated on the plurality of cell strings, and at least one common GSL disposed in common on the plurality of cell strings, and the control logic is configured to perform a control operation to cut off at least one ground selection line included in the GSL region when upper word lines of the plurality of main word lines are programmed and cut off the at least one common GSL when lower word lines of the plurality of main word lines are programmed.

According to some implementations, the present disclosure is directed to an operating method of a memory device that comprises a cell block including a plurality of cell strings and including M (where M is an integer of 2 or more) number of main word lines arranged vertically and programmed with data, a ground selection line (GSL) region including a plurality of ground selection lines coded to be electrically separated on the plurality of cell strings, and at least one common GSL disposed in common on the plurality of cell strings, includes receiving a first program command, cutting off the at least one common GSL in a program process of a first main word line as the first main word line to be programmed is included in N (where N is an integer of less than M) number of main word lines disposed in a lower portion among the M main word lines, in response to the first program command, receiving a second program command, and cutting off at least one ground selection line included in the GSL region in a program process of the second main word line as the second main word line to be programmed is disposed on the N main word lines, in response to the second program command.

According to some implementations, the present disclosure is directed to a memory system that includes a memory controller configured to communicate with a host and output a command and an address for controlling a memory operation, based on a request of the host and a memory device including a plurality of cell blocks and configured to perform a program operation in response to the command and the address from the memory controller, wherein each of the plurality of cell blocks includes a plurality of main word lines arranged vertically and programmed with data, a ground selection line (GSL) region including a plurality of ground selection lines coded to be electrically separated on the plurality of cell strings, and a plurality of special word lines disposed in a lower portion of the GSL region, and the memory device is configured to perform a control operation to cut off at least one ground selection line included in the GSL region when upper word lines of the plurality of main word lines are programmed and cut off the at least one of the plurality of special word lines when lower word lines of the plurality of main word lines are programmed.

### BRIEF DESCRIPTION OF THE DRAWINGS

Example implementations will be more clearly understood from the following detailed explanations, taken in conjunction with the accompanying drawings.

FIG. 1 is a block diagram illustrating an example of a memory system according to some implementations.

FIGS. 2A and 2B are diagrams illustrating examples of a ground selection line (GSL) region according to some implementations.

FIG. 3 is a block diagram illustrating an example of a memory device of FIG. 1 according to some implementations.

FIG. 4 is a diagram illustrating example characteristics of a channel potential with respect to a position of a cut-off line according to some implementations.

FIG. 5 is a diagram illustrating example levels of various voltages provided to word lines according to some implementations.

FIGS. 6A and 6B are diagrams illustrating example of various voltages provided to word lines according to some implementations.

FIGS. 7A and 7B are diagrams illustrating examples of a channel potential and a voltage applied to various word lines in a program operation according to some implementations.

FIG. 8 is a waveform diagram illustrating an example of a voltage applied to various word lines when an upper word line is programmed according to some implementations.

FIG. 9 is a flowchart illustrating an example of an operating method of a memory device, according to some implementations.

FIGS. 10A to 10C are diagrams illustrating examples of classifying a lower word line and an upper word line according to some implementations.

FIG. 11 is a diagram illustrating examples of a threshold voltage distribution and voltage levels of word lines according to some implementations.

FIGS. 12A and 12B are perspective views illustrating an example of a cell block according to some implementations.

FIG. 13 is a block diagram illustrating an example of a storage device to which a memory device is applied according to some implementations.

### DETAILED DESCRIPTION

Hereinafter, example implementations will be explained in detail with reference to the accompanying drawings.

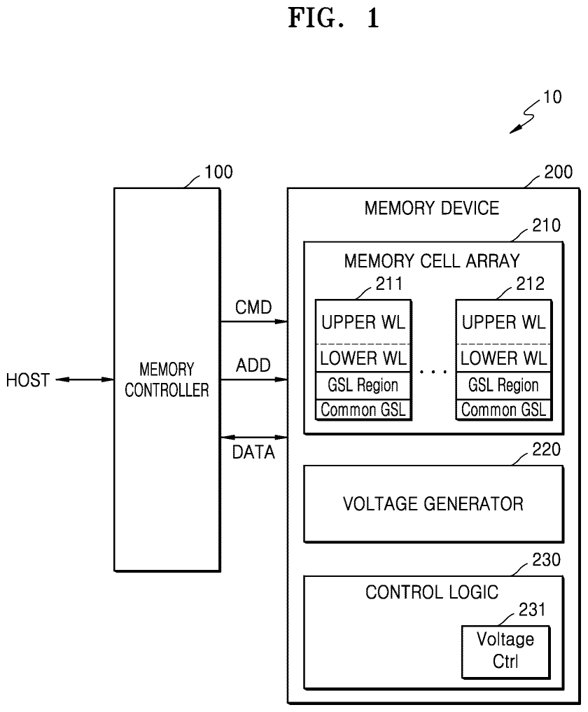

FIG. 1 is a block diagram illustrating an example of a memory system 10 according to some implementations. In FIG. 1, a memory system 10 may include a memory controller 100 and a memory device 200, and the memory device 200 may include a memory cell array 210, a voltage generator 220, and a control logic 230. In some implementations, the memory device 200 may further include various elements associated with a memory operation, such as programming/reading/erasing of data.

According to some implementations, the memory device 200 may include a non-volatile memory device. For example, the memory device 200 may include a non-volatile memory device such as NAND flash memory, vertical NAND flash memory, resistive random access memory (RAM), phase-change memory, or magnetoresistive RAM. In some implementations, the memory device 200 or the memory system 10 may be implemented as an embedded memory embedded in an electronic device, or may be implemented as an external memory attachable/detachable on/from an electronic device. For example, the memory device 200 or the memory system 10 may be implemented as various types, such as universal flash storage (UFS) memory device, embedded multimedia card (eMMC), solid state drive (SSD), UFS memory card, compact flash (CF), secure digital (SD), micro secure digital (micro-SD), mini secure digital (mini-SD), extreme digital (xD), and memory stick. The memory system 10 may be referred to as a storage device or a storage system, in terms of storing data in a non-volatile manner.

The memory controller 100 may control the memory device 200 to read data stored in the memory device 200 or program data in the memory device 200, in response to a write/read request from a host HOST. In detail, the memory controller 100 may provide an address ADD and a command CMD to the memory device 200 and may thus control program, read, and erase operations on the memory device 200. Also, data DATA to be written in the memory device 200 and the data DATA read from the memory device 200 may be transferred and received between the memory controller 100 and the memory device 200.

The memory cell array 210 may include a plurality of cell blocks. When the memory device 200 corresponds to a vertical NAND flash memory device, each of a plurality of cell blocks may include a plurality of cell strings. For example, a plurality of cell strings may be disposed based on one bit line, and in a data program/read operation, a cell string selected from among the plurality of cell strings may be electrically connected to a bit line. Also, ground selection lines may be separated on a plurality of cell strings, and for example, the ground selection lines may be electrically separated on the plurality of cell strings, based on coded ground selection lines CGSL.

A cell block may include a coded ground selection line region where a plurality of coded ground selection lines CGSL are disposed. Also, the cell block may further include at least one ground selection line which is disposed in a lower portion of the coded ground selection line region and is disposed in common on a plurality of cell strings. In some implementations, a coded ground selection line region may be referred to as a GSL region or a coded GSL region. Also, a coded ground selection line CGSL may be a line which is included in a ground selection line (GSL) region and on which coding is performed, and in the following embodiments, a coded ground selection line of a GSL region may be referred to as a ground selection line, and moreover, a ground selection line disposed outside the GSL region may be an element distinguished from a ground selection line of the GSL region and may be referred to as a common ground selection line (a comm GSL).

A plurality of ground selection transistors may be connected to each ground selection line CGSL of the GSL region, and as coding is performed on the GSL region, ground selection transistors may be programmed with a certain threshold voltage. For example, some of a plurality of ground selection transistors connected to one ground selection line may have a first threshold voltage distribution, the other some of the ground selection transistors may have a second threshold voltage distribution, and a second threshold voltage level may be higher than a first threshold voltage level. Also, when the first threshold voltage and the second threshold voltage distribution have a program state, programming may be performed on a plurality of ground selection transistors connected to one ground selection line in a coding process. In some implementations, when the first threshold voltage distribution corresponds to an erase state, programming may not be performed on ground selection transistors coded with the first threshold voltage distribution among ground selection transistors connected to one ground selection line in a coding process.

In some implementations, at least one of a plurality of ground selection lines CGSL of the GSL region may be used as a dummy line. For example, ground selection transistors connected to a ground selection line CGSL used as the dummy line may be programmed with one threshold voltage. The dummy line may be disposed for enhancing a channel potential boundary characteristic between the GSL region and external lines thereof, or may be disposed for enhancing a channel potential boundary characteristic between lines of the GSL region. For example, the dummy line may be disposed at various positions of the GSL region, so as to enhance a retention characteristic or a hot carrier injection (HCI) characteristic of various lines.

In some implementations, when a structure where a common source line CSL, a common ground selection line, the GSL region, and a plurality of main word lines are sequentially arranged in a vertical direction from a substrate is assumed, the dummy line may be disposed under the GSL region, and thus, may be disposed adjacent to the common source line (or a common ground selection line). In some implementations, the dummy line may be disposed in an upper portion of the GSL region, and thus, may be disposed adjacent to the plurality of main word lines. In some implementations, the dummy line may be disposed at an arbitrary position between ground selection lines CGSL. Also, the GSL region may include two or more dummy lines, and thus, dummy lines may be disposed at various positions of the GSL region.

According to some implementations, the plurality of main word lines may be vertically disposed on the substrate and may be classified into upper word lines and lower word lines, based on a disposed position. For example, when M number of main word lines are included in a cell block, N number of main word lines relatively disposed at a lower end may be classified into lower word lines, and main word lines disposed on the N main word lines may be classified into upper word lines.

In a case where a program operation is performed on main word lines, an electrical connection between each of the main word lines and the common source line is disconnected, and a channel corresponding to each of the main word lines may have a floating state. For example, a channel corresponding to main word lines may be floated by cutting off at least one line between the main word lines and the common source line in a program process, and an operation of performing cutoff may include an operation of turning off transistors or cells connected to a cut-off line.

According to some implementations, based on control by the control logic 230, a position of a cut-off line may vary based on a position of a main word line where programming is performed. For example, the cell block may further include special word lines disposed between the GSL region and the common source line, and the special word lines may include different various kinds of lines along with a common ground line described above. A cut-off position may vary based on the control of a voltage level provided to the GSL region and special word lines, and for example, in a case where programming is performed on a main word line included in a lower word line, a control operation may be performed to cut off at least one of the special word lines, and for example, a common GSL may be cut off.

On the other hand, when programming is performed on a main word line included in an upper word line, at least one line included in the GSL region may be cut off. For example, the plurality of ground selection lines CGSL of the GSL region may include at least one first dummy line disposed in an upper portion of the GSL region, at least one second dummy line disposed in a lower portion of the GSL region, and ground selection lines CGSL which are disposed between the first dummy line and the second dummy line and are programmed to have at least two threshold voltage distributions, based on coding, and in an embodiment, based on control by the control logic 230, the first dummy line may be cut off, or the second dummy line may be cut off, or at least one of the plurality of ground selection lines CGSL may be cut off.

As main word lines are floated in a program operation and a program voltage having a high level is applied to a main word line where programming is performed, a potential of a channel corresponding to the main word line where programming is performed may largely increase. Also, the potential of the channel may gradually decrease in a direction of a cut-off line from the main word line where programming is performed, and threshold voltage characteristic of lines at positions at which a variation of the channel potential is large (or positions at which a slope of a channel potential is large) may be deteriorated due to HCI.

Based on the arrangement of various lines of the cell block described above, when programming is performed on a main word line included in a lower word line, a variation of a channel potential may be large at a position corresponding to the GSL region. On the other hand, when programming is performed on a main word line included in an upper word line, a variation of a channel potential may be relatively small at the position corresponding to the GSL region.

According to some implementations, a position of a cut-off line may be changed based on a position of a main word line where programming is performed, based on the channel potential characteristic described above, thereby decreasing or preventing a reduction in characteristic of the ground selection line CGSL of the GSL region. For example, in a case where the main word line included in the lower word line is programmed, a variation of a potential may be relatively large at a position of a channel corresponding to the GSL region, and thus, a line (for example, a common GSL) at a position under the GSL region may be cut off. On the other hand, in a case where the main word line included in the upper word line is programmed, a variation of a potential may be relatively small at the position of the channel corresponding to the GSL region, and thus, a line (for example, at least one ground selection line of the GSL region) at a position above the common GSL may be cut off. In this case, the ground selection lines of the GSL region may be prevented from being put in a floating state, and thus, a risk of HCI occurring in the ground selection lines of the GSL region may decrease.

Moreover, in a case where the main word line corresponding to the upper word line is programmed, a potential variation of a channel corresponding to the GSL region may be relatively small, but the accumulation of stress occurring in the GSL region may increase as a program operation is repeatedly performed on a plurality of main word lines, and due to this, there may still be an HCI risk of the GSL region. However, according to some implementations, a common source voltage having a certain level or a ground voltage level transferred through the common source line may be applied to a channel corresponding to the ground selection lines of the GSL region, and thus, a potential of the channel corresponding to the GSL region may be intactly maintained. In this case, even when a plurality of program operations are repeatedly performed, an HCI risk of the GLS region may be removed, and thus, a reduction in threshold voltage characteristic of the GSL region may be prevented.

The GSL region may need to secure a threshold voltage characteristic for enhancing the electrical separation performance of ground selection lines corresponding to cell strings in association with a memory operation of the memory device 200. According to some implementations, a position of a cut-off line may be changed based on a position of a programmed main word line, and a voltage level applied to various lines of the cell block may be controlled, and thus, a threshold voltage characteristic of the GSL region may be well maintained, thereby enhancing the reliability of data.

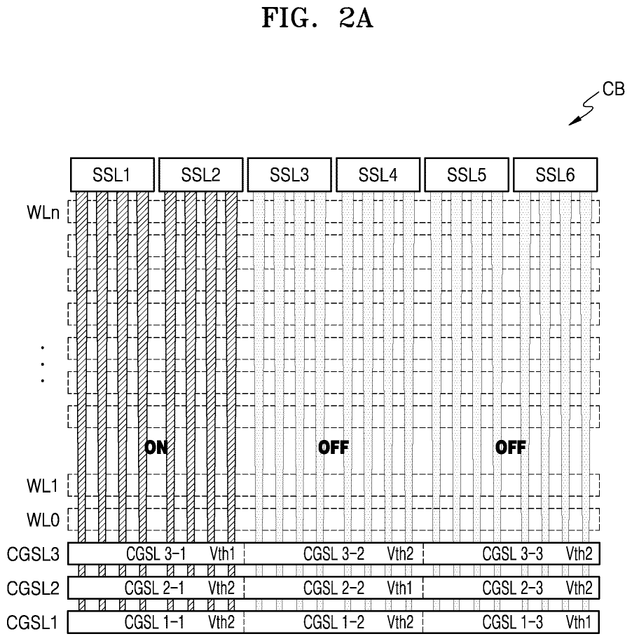

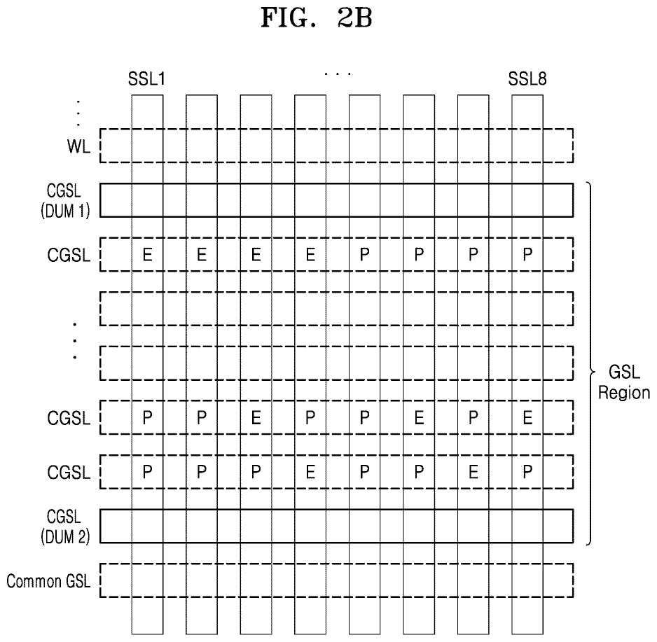

FIGS. 2A and 2B are diagrams illustrating examples of a GSL region according to some implementations.

In a case where ground selection lines are physically separated on each cell string, it may be needed to form a dummy hole for separating the ground selection lines, and thus, the degree of integration of a memory device may be reduced. On the other hand, in FIG. 2A, instead of removing a dummy hole, a GSL region may be provided in a cell block, for the electrical separation of ground selection lines. In FIG. 2A, a case is illustrated where the GSL region includes first to third ground selection lines CGSL1 to CGSL3, based on first to sixth string selection lines SSL1 to SSL6. In FIG. 2A, it is illustrated by a dotted line that each ground selection line includes three regions, but this is for conceptually illustrating an electrical separation characteristic, and each of the first to third ground selection lines CGSL1 to CGSL3 may physically correspond to one line which is disposed in the first to sixth string selection lines SSL1 to SSL6 in common.

Ground selection transistors respectively connected to the first to third ground selection lines CGSL1 to CGSL3 may be programmed with a certain threshold voltage. For example, in association with the third ground selection line CGSL3, ground selection transistors of a third-1 region CGSL3-1 corresponding to the first and second string selection lines SSL1 to SSL2 may be programmed with a first threshold voltage Vth1. On the other hand, ground selection transistors of the third-2 region CGSL3-2 and ground selection transistors of the third-3 region CGSL3-3 corresponding to the third to sixth string selection lines SSL3 to SSL6 may be programmed with a second threshold voltage Vth2 which is higher than the first threshold voltage Vth1.

Likewise, in association with the second ground selection line CGSL2, ground selection transistors of a second-2 region CGSL2-2 corresponding to the third and fourth string selection lines SSL3 and SSL4 may be programmed with the first threshold voltage Vth1. On the other hand, ground selection transistors of second-1 region CGSL2-1 and second-3 region CGSL2-3 corresponding to the first and second string selection lines SSL1 and SSL2 and the fifth and sixth string selection lines SSL5 and SSL6 may be programmed with the second threshold voltage Vth2. Also, in association with the first ground selection line CGSL1, ground selection transistors of a first-3 region CGSL1-3 corresponding to the fifth and sixth string selection lines SSL5 and SSL6 may be programmed with the first threshold voltage Vth1. On the other hand, ground selection transistors of a first-1 region CGSL1-1 and a first-2 region CGSL1-2 corresponding to the first to fourth string selection lines SSL1 to SSL4 may be programmed with the second threshold voltage Vth2.

When one of the first and second string selection lines SSL1 and SSL2 is selected, a ground selection voltage having a level between the first threshold voltage and the second threshold voltage may be provided to the third ground selection line CGSL3, and thus, the ground selection transistors of the third-1 region CGSL3-1 may be turned on, and the ground selection transistors of the third-2 region CGSL3-2 and the third-3 region CGSL3-3 may be turned off. Accordingly, cell strings of the third to sixth string selection lines SSL3 to SSL6 may be electrically separated from the common source line.

Also, when one of the third and fourth string selection lines SSL3 and SSL4 is selected, a ground selection voltage having a level between the first threshold voltage and the second threshold voltage may be provided to the second ground selection line CGSL2, and thus, the ground selection transistors of the second-2 region CGSL2-2 may be selectively turned on. Also, when one of the fifth and sixth string selection lines SSL5 and SSL6 is selected, a ground selection voltage having a level between the first threshold voltage and the second threshold voltage may be provided to the first ground selection line CGSL1, and thus, the ground selection transistors of the first-3 region CGSL1-3 may be selectively turned on.

In FIG. 2A, a case is illustrated where three ground selection lines are disposed on the first to sixth string selection lines SSL1 to SSL6, and thus, ground selection lines are electrically separated by units of two cell strings. However, the GSL region may be variously implemented, and for example, a various number of ground selection lines may be provided in the GSL region, and thus, ground selection lines may be electrically separated by units of a various number of cell strings. Also, in FIG. 2A, the illustration of a ground selection line used as a dummy line included in the GSL region is omitted for describing an electrical separation characteristic, but as in the embodiment described above, at least one dummy line may be disposed between word lines WL0 to WLn and the third ground selection line CGSL3.

FIG. 2B illustrates an example of a GSL region according to some implementations. In FIG. 2B, the GSL region may include a plurality of ground selection lines CGSL, the plurality of ground selection lines CGSL may include a first dummy line Dum1 and a second dummy line Dum2, and the GSL region may include ground selection lines CGSL between the first dummy line Dum1 and the second dummy line Dum2. Dummy cells of each of the first dummy line Dum1 and the second dummy line Dum2 may be programmed to have one threshold voltage distribution. Also, the ground selection lines CGSL between the first dummy line Dum1 and the second dummy line Dum2 may be referred to as a coding region where coding is performed, and ground selection transistors connected to a ground selection line CGSL of the coding region may have a first threshold voltage distribution and a second threshold voltage distribution. For example, in FIG. 2B, a first threshold voltage is illustrated in an erase state E, and a second threshold voltage is illustrated in a program state P. However, the present disclosure is not limited thereto, each of a first threshold voltage level and a second threshold voltage level may correspond to a programmed state, and the first threshold voltage may have a level which is lower than the second threshold voltage.

Ground selection transistors may be turned on or off based on a level of a voltage provided to the ground selection lines CGSL. For example, when a voltage having a level between the first threshold voltage and the second threshold voltage is provided to the ground selection line CGSL, a ground selection transistor programmed with the first threshold voltage may be turned on, and a ground selection transistor programmed with the second threshold voltage may be turned off. For example, all ground selection transistors of a selection cell string may be turned on by controlling a voltage level provided to the ground selection lines CGSL. On the other hand, in unselected cell strings, at least one ground selection transistor may be turned off.

Furthermore, in FIG. 2B, at least one ground selection line GSL of the GSL region may be used as a dummy line, and for example, the first dummy line Dum1 adjacent to a main word line WL and the second dummy line Dum2 adjacent to a common GSL are illustrated. A plurality of dummy cells (or dummy transistors) connected to each of the first dummy line Dum1 and the second dummy line Dum2 may be programmed with a certain threshold voltage, and for example, the dummy cells may be programmed to have a threshold voltage level between the first threshold voltage and the second threshold voltage. In some implementations, the dummy cells may be programmed with a threshold voltage level corresponding to the second threshold voltage.

Furthermore, when a cell block has a vertical NAND structure, various kinds of lines may be further disposed in a lower portion of the GSL region, and the lines may be referred to as a special word line. The special word line may include a common GSL described above, and two or more common GSLs may be included in the cell block. Also, the special word line may further include at least one erase control line (or a gate induced drain leakage (GIDL) line) and one or more common dummy lines as additional dummy lines disposed outside the GSL region. The erase control line may cause GIDL and may thus be disposed for enhancing an erase characteristic of the cell block, and for example, an erase voltage may be provided to a channel through transistors connected to the erase control line. Also, each of the special word lines described above may be programmed to have one threshold voltage distribution.

In some implementations, various lines included in the cell block may be referred to as a word line connected to a row decoder of a memory device. In some implementations, an element referred to as a word line may be understood as a concept including various lines included in the cell block.

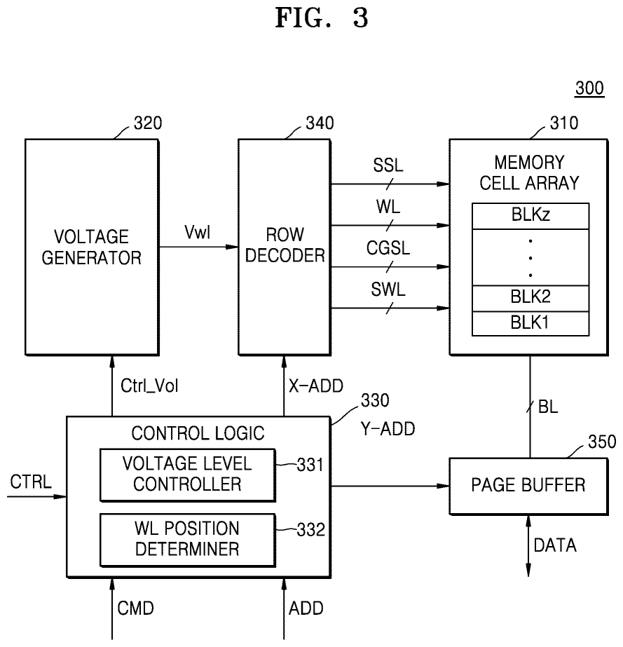

FIG. 3 is a block diagram illustrating an example of the memory device 200 of FIG. 1 according to some implementations. In FIG. 3, a memory device 300 may include a memory cell array 310, a voltage generator 320, a control logic 330, a row decoder 340, and a page buffer 350. In some implementations, the memory device 300 may further include different various elements, associated with a memory operation, such as a data input/output (I/O) circuit and an I/O interface.

The memory cell array 310 may include a plurality of cell blocks BLK1 to BLKz. Also, the row decoder 340 may be connected to each cell block through word lines, and the word lines may include main word lines WL, string selection lines SSL, and ground selection lines CGSL and special word lines SWL of a GSL region. Also, the page buffer 350 may be connected to each cell block through bit lines BL. Each of the memory cells may store one or more bits, and for example, each memory cell may correspond to a multi level cell (MLC), a triple level cell (TLC), or a quad level cell (QLC).

The control logic 330 may program data in the memory cell array 310 or may output various internal control signals for reading data from the memory cell array 310, based on a command CMD, an address ADD, and a control signal CTRL each received from a memory controller. Also, the voltage generator 320 may generate various voltages used in the memory device 300, and for example, may generate a word line voltage Vwl provided to word lines in association with data program, read, and erase operations.

The control logic 330 may output a voltage control signal Ctrl_vol for controlling a level of the word line voltage Vwl generated by the voltage generator 320. According to some implementations, the control logic 330 may include a voltage level controller 331 and a word line position determiner 332 and may output different voltage control signals Ctrl_vol, based on a determination result of a position of a main word line where programming is to be performed. In FIG. 3, the voltage level controller 331 and the word line determiner 332 are illustrated as elements included in the control logic 330, but the present disclosure is not limited thereto and the voltage level controller 331 and/or the word line position determiner 332 may be provided outside the control logic 330. Also, in some implementations, a main word line, where programming is to be performed, of a plurality of main word lines may be referred to as a selection word line.

The control logic 330 may provide a row address X-ADD to the row decoder 340 and may provide a column address Y-ADD to the page buffer 350. In some implementations, the word line position determiner 332 may determine a position of a selection word line corresponding to a main word line where programming is to be performed, based on an address ADD, and for example, may determine whether the selection word line corresponds to a predetermined lower word line or corresponds to a predetermined upper word line. The voltage level controller 331 may output the voltage control signal Ctrl_vol for adjusting a level of a voltage provided to word lines, based on a determination result of a position of the selection word line. For example, when the selection word line corresponds to the upper word line, the voltage level controller 331 may output the voltage control signal Ctrl_vol for cutting off at least one line of the GSL region of the cell block. On the other hand, when the selection word line corresponds to the lower word line, the voltage level controller 331 may output the voltage control signal Ctrl_vol for cutting off at least one line of the special word line SWL of the cell block, and for example, may output the voltage control signal Ctrl_vol for cutting off a common GSL.

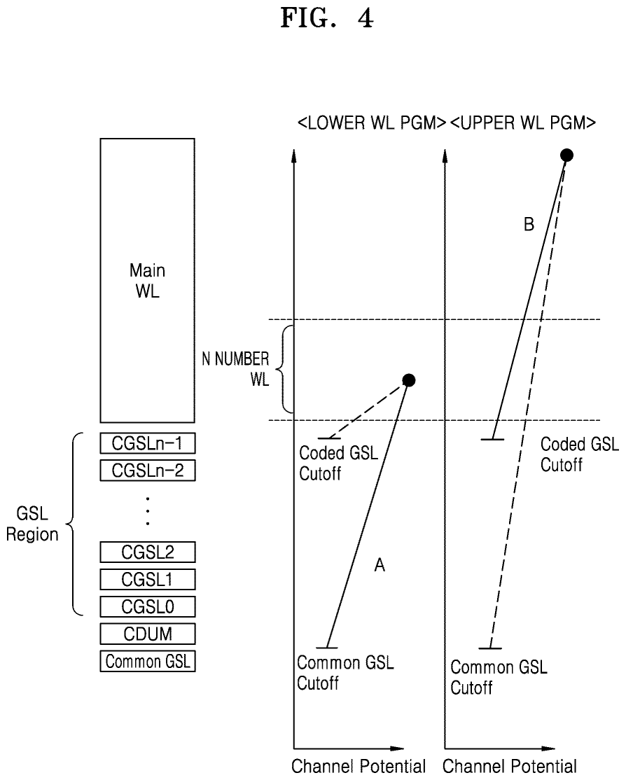

FIG. 4 is a diagram illustrating example characteristics of a channel potential with respect to a position of a cut-off line according to some implementations. In FIG. 4, a cell block may include a GSL region and a common GSL along with a plurality of main word lines. For example, the GSL region may include a plurality of ground selection lines, and for example, first to nth ground selection lines CGSL0 to CGSLn-1 are illustrated. Also, as an example of word lines disposed below the GSL region, a common dummy line CDUM and a common GSL are illustrated. In some implementations, one common GSL and one common dummy line are illustrated as special word lines disposed below the GSL region, but as described above, a cell block according to some implementations may include various kinds and number of special word lines.

N number of main word lines disposed in a relatively lower portion among a plurality of main word lines which are vertically disposed may be classified into a lower word line. A potential of a channel corresponding to a selection word line may have a very large value in a program operation, and the potential of the channel may have a characteristic which is reduced progressively in a line direction a cut-off lower portion. In this case, when a lower word line adjacent to the GSL region is programmed, a slope of a potential of a channel corresponding to the GSL region may have a large value, and in this case, an HCI risk of each of ground selection lines CGSL0 to CGSLn-1 of the GSL region may be relatively large. On the other hand, when an upper word line which is not adjacent to the GSL region is programmed, the slope of the potential of the channel corresponding to the GSL region may have a relatively small value, and in this case, an HCI risk of each of the ground selection lines CGSL0 to CGSLn-1 of the GSL region may be relatively small.

Based on a channel potential characteristic illustrated in FIG. 4, when a lower word line is programmed, the common GSL may be cut off as at least one of special word lines, and thus, a slope of a channel potential corresponding to the GSL region may have a shape A. That is, when the lower word line is programmed, at least one line of special word lines disposed in a lower portion in a cell block may be cut off, and thus, the slope of the potential of the channel corresponding to the GSL region may decrease. On the other hand, when the upper word line is programmed, the slope of the channel potential corresponding to the GSL region may be relatively small, and as at least one line of the GSL region is cut off, the slope of the channel potential corresponding to the GSL region may have a shape B. That is, in a case where the upper word line is programmed, even when a line of the GSL region is cut off, a variation of the channel potential corresponding to the GSL region may not be large, and thus, an HCI risk of each of the ground selection lines CGSL0 to CGSLn-1 of the GSL region may be relatively small.

When an upper line (for example, an nth ground selection line CGSLn-1 of the GSL region) is cut off as the upper word line is programmed, first to nth-1 ground selection lines CGSL0 to CGSLn-2 under the nth ground selection line CGSLn-1 may not be floated. For example, a turn-on voltage may be applied to the special word lines of the cell block, and thus, a common source voltage having a certain level or a ground voltage level may be applied to the channel corresponding to the GSL region, whereby the potential of the channel corresponding to the GSL region may maintain a certain value. Accordingly, as programming is repeatedly performed on a plurality of main word lines, even when stress is accumulated, an HCI risk of each of the ground selection lines CGSL0 to CGSLn-1 of the GSL region may be reduced or removed, and a reduction in threshold voltage characteristic of the ground selection lines CGSL0 to CGSLn-1 may be prevented.

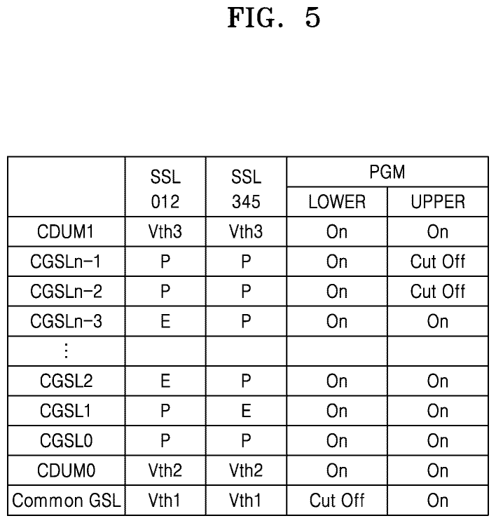

FIG. 5 is a diagram illustrating example levels of various voltages provided to word lines according to some implementations. In FIG. 5, first to sixth string selection lines SSL0 to SSL5 corresponding to a plurality of cell strings are illustrated, and a case is illustrated where ground selection lines are electrically separated on cell strings corresponding to the first to third string selection lines SSL0 to SSL2 and cell strings corresponding to the fourth to sixth string selection lines SSL3 to SSL5, based on coding on the ground selection lines CGSL0 to CGSLn-1.

Furthermore, in FIG. 5, a case is illustrated where a first common dummy line CDUM0 disposed under the GSL region and a second common dummy line CDUM1 disposed above the GSL region are further provided as an additional word line. For example, the first ground selection line CGSL0 and the nth-1 and nth ground selection lines CGSLn-2 and CGSLn-1 may be used as a dummy line, and thus, ground selection transistors connected to the first, nth-1, and nth ground selection lines CGSL0, CGSLn-2, and CGSLn-1 may be programmed with a certain threshold voltage level. On the other hand, each of ground selection transistors connected to the second to nth-2 ground selection lines CGSL1 to CGSLn-3 may have a first threshold voltage level (for example, an erase state E) or a second threshold voltage level (for example, a program state P). Also, transistors respectively connected to special word lines may have one threshold voltage distribution, and threshold voltage distributions of the common GSL, the first common dummy line CDUM0, and the second common dummy line CDUM1 are illustrated by Vth1 to Vth3.

According to some implementations, in a case where the common GSL is cut off when the lower word line is programmed, a voltage signal for turning off transistors connected to the common GSL may be provided to the common GSL. Furthermore, in a program process on the lower word line, a turn-on voltage may be applied to different various lines, for example, the first and second common dummy lines CDUM0 and CDUM1 and the first to nth ground selection lines CGSL0 to CGSLn-1 of the GSL region.

On the other hand, in a case where the nth-1 and nth ground selection lines CGSLn-2 to CGSLn-1 disposed in an upper portion of the GSL region and used as dummy lines are cut off when the upper word line is selected in a program operation, a voltage signal for turning off ground selection transistors connected to the nth-1 and nth ground selection lines CGSLn-2 to CGSLn-1 may be provided to the nth-1 and nth ground selection lines CGSLn-2 to CGSLn-1. Also, when the nth-1 and nth ground selection lines CGSLn-2 to CGSLn-1 of the GSL region are cut off, a turn-on voltage may be applied to word lines disposed under the nth-1 and nth ground selection lines CGSLn-2 to CGSLn-1 so as to provide the common source voltage to the channel corresponding to the GSL region.

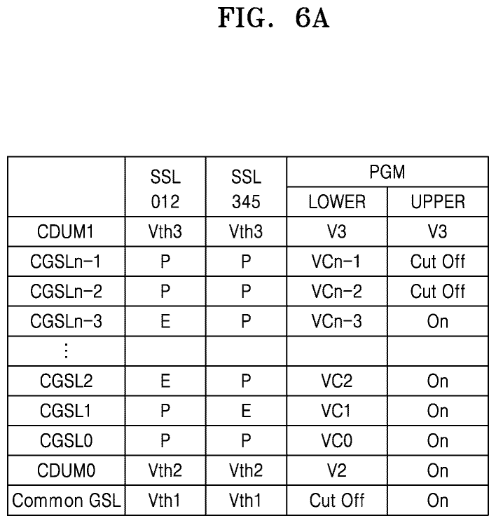

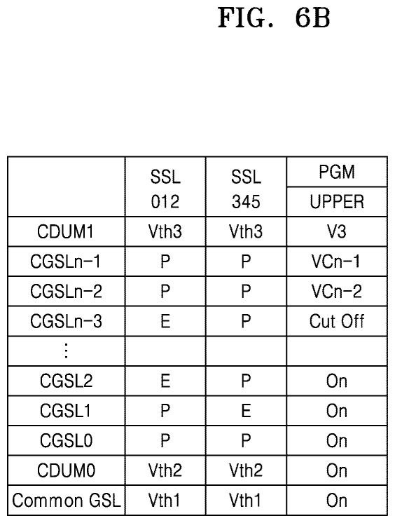

FIGS. 6A and 6B are diagrams illustrating examples of various voltages provided to word lines according to some implementations. In FIG. 6A, when a lower word line is programmed, a common GSL may be cut off, and thus, a channel corresponding to word lines disposed above the common GSL may have a floating state. At this time, a threshold voltage characteristic of ground selection lines of a GSL region may decrease due to an adverse effect of HCI, based on a potential of a channel corresponding to the GSL region. In some implementations, the potential of the channel corresponding to the GSL region may vary based on a level of a voltage provided to the word lines disposed above the common GSL, and a slope of the potential of the channel corresponding to the GSL region may decrease based on a care operation of adjusting a level of a voltage provided to the word lines disposed above the common GSL.

In FIG. 6A, in association with the care operation, voltages provided to common dummy lines CDUM0 and CDUM1 and first to nth ground selection lines CGSL0 to CGSLn-1 of the GSL region are illustrated by V2, V3, and VC0 to VCn-1, the voltages V2 and V3 may turn on the common dummy lines CDUM0 and CDUM1, the voltages VC0 to VCn-1 may turn on the first to nth ground selection lines CGSL0 to CGSLn-1, the voltages V2 and V3 may have an arbitrary level, based on threshold voltages of the common dummy lines CDUM0 and CDUM1, and voltages VC0 to VCn-1 may have an arbitrary level, based on threshold voltage distributions of the first to nth ground selection lines CGSL0 to CGSLn-1.

Furthermore, in FIG. 6A, when an upper word line is programmed, the nth-1 and nth ground selection lines CGSLn-2 an CGSLn-1 may be cut off. Also, in some implementations, a turn-on voltage may be applied to various word lines disposed under a cut-off line, and a common source voltage may be applied to the channel corresponding to the GSL region. At this time, a channel corresponding to the common dummy line CDUM1 disposed above the GSL region may have a floating state, and thus, the voltage V3 having an arbitrary level may be applied to the common dummy line CDUM1 disposed above the GSL region in association with the care operation described above.

Furthermore, FIG. 6B illustrates a case where a ground selection line of a coding region in the GSL region is cut off when programming the upper word line. For example, when the nth-2 ground selection line CGSLn-3 of the second to nth-2 ground selection lines CGSL1 to CGSLn-3 included in the coding region is cut off, voltages VCn-2 and VCn-1 associated with the care operation described above may be provided to the nth-1 and nth ground selection lines CGSLn-2 and CGSLn-1 disposed above the nth-2 ground selection line CGSLn-3.

Also, as a turn-on voltage is applied to word lines disposed under the nth-2 ground selection line CGSLn-3, the common source voltage may be applied to the channel corresponding to the GSL region.

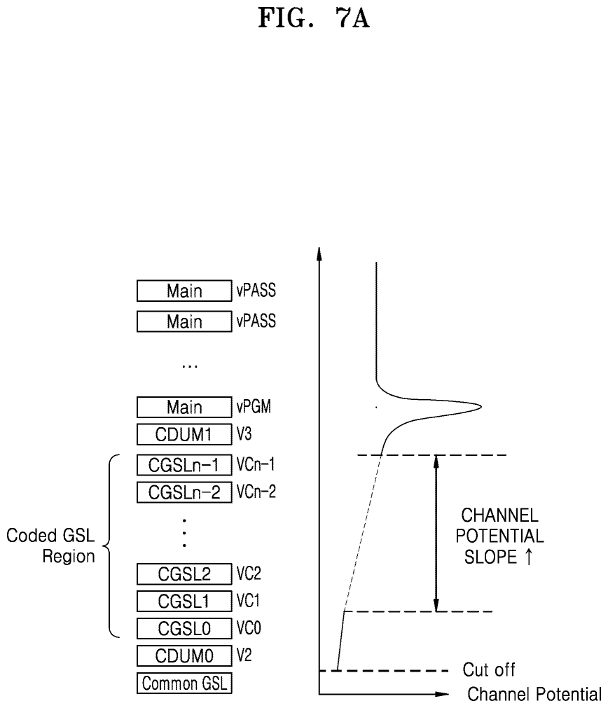

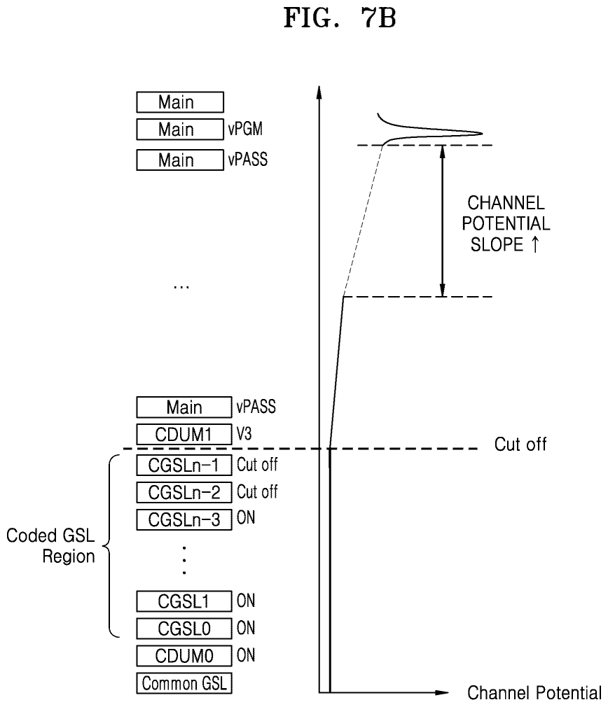

FIGS. 7A and 7B are diagrams illustrating examples of a channel potential and a voltage applied to various word lines in a program operation according to some implementations. In FIGS. 6A and 7A, as a lower word line is programmed, a program voltage vPGM may be provided to a main word line where programming is to be performed, and a pass voltage vPASS may be provided to other main word lines. Also, a common GSL may be cut off, and a turn-off voltage may be provided to the common GSL. Also, a channel corresponding to word lines disposed above the common GSL may be floated, and voltages having a level associated with a care operation may be provided to the word lines disposed above the common GSL. For example, the level associated with the care operation described above may have a level which turns on a transistor connected to a corresponding line. Also, a potential of a channel may vary based on levels of voltages provided to the word lines disposed above the common GSL, and for example, a level may be set to decrease a variation of a potential of a channel corresponding to the GSL region.

In FIGS. 6A and 7B, as an upper word line is programmed, the program voltage vPGM may be provided to a main word line where programming is to be performed, and the pass voltage vPASS may be provided to other main word lines. Also, in a case where nth-1 and nth ground selection lines CGSLn-2 and CGSLn-1 of the GSL region are cut off, a turn-off voltage may be provided to the nth-1 and nth ground selection lines CGSLn-2 and CGSLn-1.

Also, in some implementations, a channel corresponding to word lines disposed under the nth-1 and nth ground selection lines CGSLn-2 and CGSLn-1 may not be floated, the common GSL may be turned on, and a common source voltage may be applied to a channel corresponding to the GSL region. In this case, as illustrated in FIG. 7B, a potential of the channel corresponding to the GSL region may be intactly maintained, and an HCI risk of the channel corresponding to the GSL region may be reduced or removed. In this case, voltage signals having a turn-on level may be provided to the word lines disposed under the nth-1 and nth ground selection lines CGSLn-2 and CGSLn-1 so that the common source voltage is applied to the channel corresponding to the word lines disposed under the nth-1 and nth ground selection lines CGSLn-2 and CGSLn-1.

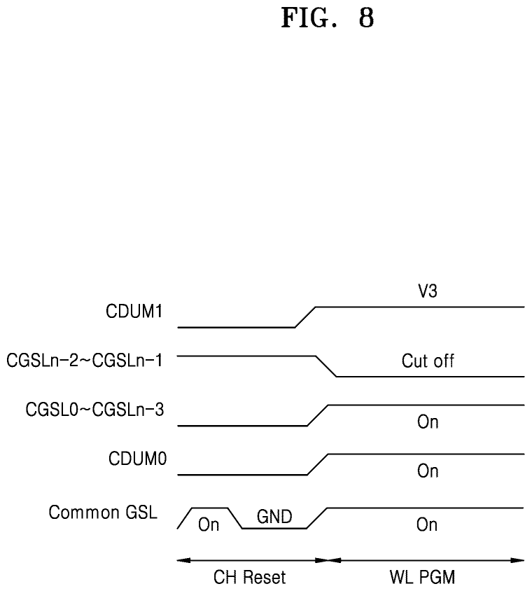

FIG. 8 is a waveform diagram illustrating an example of a voltage applied to various word lines when an upper word line is programmed according to some implementations.

Before voltages having a target level are provided to various word lines of a cell block so as to perform programming, a channel reset process of emitting an electron of a channel may be performed, and a voltage having a level for turning on a corresponding line may be provided to various word lines in the channel reset process. In FIG. 8, common dummy lines and ground selection lines of the GSL region may maintain a turn-on state in the channel reset process, and the common GSL may be turned on during a certain initial period.

Subsequently, according to some implementations, when programming is performed on an upper word line, a voltage having a target level may be applied to various word lines, and the voltage having the target level such as a care voltage, a cutoff voltage, or a turn-on voltage may be provided based on a word line. For example, as nth-1 and nth ground selection lines CGSLn-2 and CGSLn-1 are cut off, a level of a voltage provided to the nth-1 and nth ground selection lines CGSLn-2 and CGSLn-1 may be reduced. Also, a voltage having a level associated with the care operation described above may be applied to a common dummy line CDUM1 disposed above the GSL region, and the turn-on voltage may be applied to word lines disposed under the nth-1 and nth ground selection lines CGSLn-2 and CGSLn-1. For example, a level corresponding to the turn-on voltage may be set to be higher than a voltage level of the channel reset process.

A waveform diagram illustrated in FIG. 8 may be an example, and the present disclosure is not limited thereto and a voltage level provided to a word line may be variously set. That is, with respect to a cut-off line, voltages having various levels may be provided to word lines disposed thereon in association with the care operation, and with respect to the cut-off line, the turn-on voltage for transferring a common source voltage may be provided to word lines disposed thereunder.

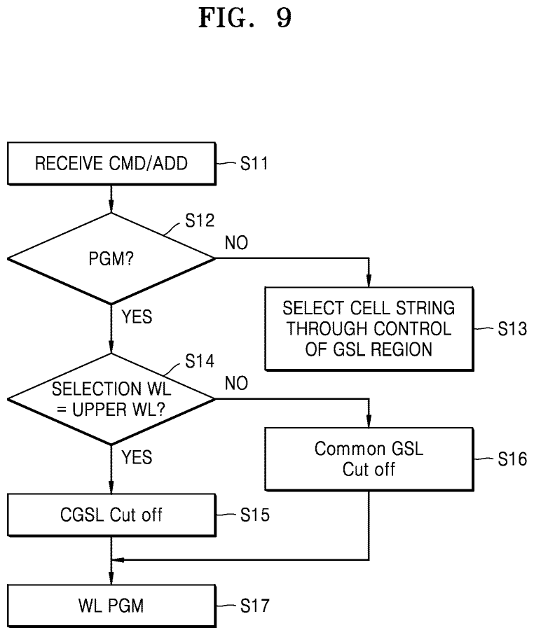

FIG. 9 is a flowchart illustrating an example of an operating method of a memory device according to some implementations. In FIG. 9, the memory device may perform a memory operation, based on a command CMD and an address ADD from a memory controller, and may receive the command CMD and the address ADD in operation S11, and in operation S12, the memory device may determine whether a program operation is requested, based on a decoding result of the command CMD. The memory device may include a plurality of cell blocks, and each of the cell blocks may include a GSL region according to some implementations. When the command CMD from the memory controller corresponds to a data read request, the memory device may select a cell string where data is to be read, based on the address ADD, and may control a voltage level provided to ground selection lines of the GSL region so as to electrically separate cell strings in operation S13.

Also, when the command CMD from the memory controller corresponds to a data program request, the memory device may determine whether a selection word line corresponds to a lower word line or corresponds to an upper word line, based on the address ADD. When the selection word line corresponds to the upper word line as a determination result, the memory device may cut off at least one line of the GSL region in operation S15, and when the selection word line corresponds to the lower word line, the memory device may cut off a common GSL as a word line outside the GSL region in operation S16. As described above, a cutoff operation may be performed on at least one line, and then, a program operation on a main word line may be performed in operation S17.

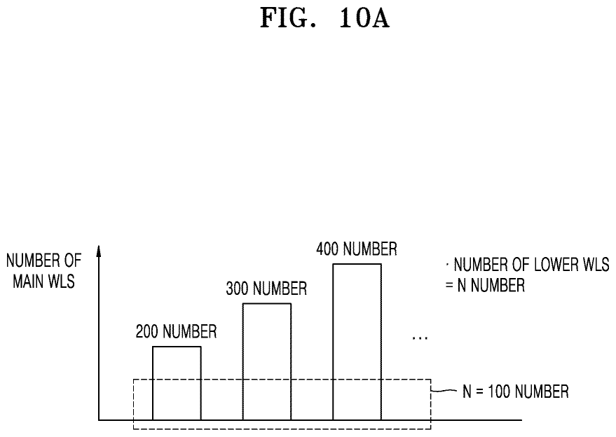

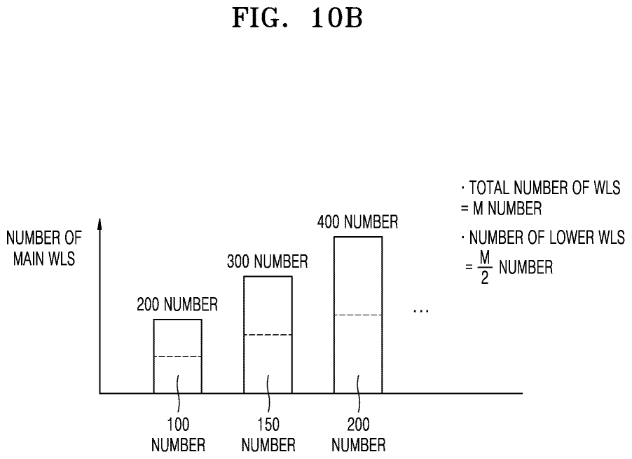

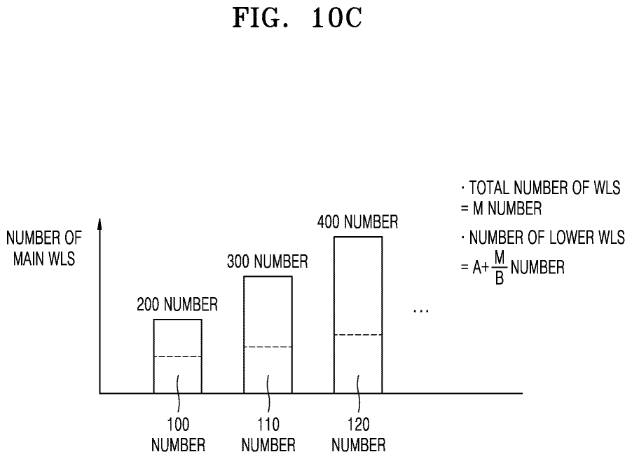

FIGS. 10A to 10C are diagrams illustrating examples of classifying a lower word line and an upper word line according to some implementations. The number of main word lines illustrated in FIGS. 10A to 10C may be an example, and the number of main word lines of a cell block according to some implementations may have various values.

In FIG. 10A, a cell block may include a various number of main word lines, and for example, a case is illustrated where the cell block includes 200 main word lines, or includes 300 main word lines, or includes 400 main word lines. For example, cell blocks of a memory device may include a same number of main word lines, and each of the cell blocks may include 200, 300, or 400 main word lines. Also, in some implementations, the cell blocks included in the memory device may include a different number of main word lines, some cell blocks may include 200 main word lines, and some other cell blocks may include 300 or 400 main word lines.

In each cell block, the number of main word lines classified into a lower word line may be defined as a fixed value (for example, an N number). For example, regardless of the number of main word lines included in a cell block, a fixed number of (for example, 100) main word lines disposed in a lower portion may be classified into a lower word line. Accordingly, when cell blocks include a different number of main word lines, the number of lower word lines of the cell blocks may be equal to one another, and the number of upper word lines of the cell blocks may differ.

Furthermore, in FIG. 10B, in each cell block, the number of main word lines classified into a lower word line among all main word lines corresponding to an M number may be defined as a fixed ratio of the total number of main word lines. For example, in a case where the ratio is set to M/2, when 200 main word lines are included in a cell block, the number of lower word lines may correspond to 100, and when 400 main word lines are included in a cell block, the number of lower word lines may correspond to 200. Accordingly, when cell blocks include a different number of main word lines, the number of lower word lines of the cell blocks may have different values.

Furthermore, in FIG. 10C, a case is illustrated where, as the total number of main word lines included in a cell block increases, the number of main word lines classified into a lower word line in the cell block increases. For example, 100 lower word lines may be defined on a certain number of total main word lines (for example, 200), and classification may be performed so that, as the total number of main word lines increases, the number of lower word lines increases at a certain ratio of the increment. For example, when it is assumed that the number of 10 lower word lines increases as the number of 100 main word lines increases, 110 main word lines disposed in a lower portion may be classified into a lower word line when total 300 main word lines are included in a cell block, and 120 main word lines disposed in a lower portion may be classified into a lower word line when total 400 main word lines are included in a cell block.

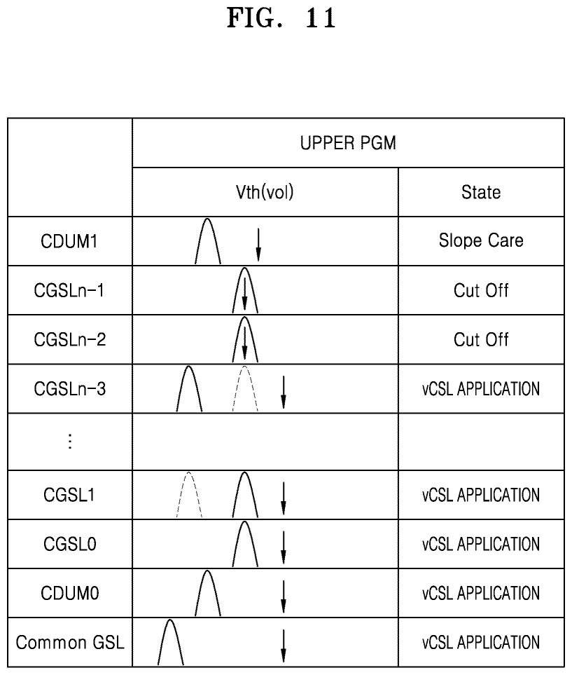

FIG. 11 is a diagram illustrating examples of a threshold voltage distribution and voltage levels of word lines according to some implementations. In FIG. 11, a case where an upper word line among a plurality of main word lines are programmed is illustrated.

In FIG. 11, ground selection lines CGSL0, CGSLn-2, and CGSLn-1 corresponding to dummy lines in a GSL region may be programmed with one threshold voltage, and ground selection lines CGSL1 to CGSLn-3 of a coding region in the GSL region may be programmed with first and second threshold voltages. In some implementations, a threshold voltage of dummy lines corresponds to the second threshold voltage, but the threshold voltage of the dummy lines may be programmed to have a level between the first threshold voltage and the second threshold voltage.

Furthermore, common dummy lines CDUM1 and CDUM0 may also be programmed with one arbitrary threshold voltage, and in FIG. 11, a case is illustrated where the common dummy lines CDUM1 and CDUM0 are programmed with a threshold voltage distribution which is lower than a dummy line of the GSL region, but the present disclosure is not limited thereto. Moreover, a common GSL may be programmed with one threshold voltage.

According to some implementations, when arbitrary ground selection lines (for example, nth-1 and nth ground selection lines CGSLn-2 and CGSLn-1) of the GSL region are cut off, a voltage having a level for the slope care of a channel may be applied to the common dummy line CDUM1, and a turn-on voltage for applying a common source voltage vCSL to the channel may be applied to word lines disposed under the nth-1 and nth ground selection lines CGSLn-2 and CGSLn-1. According to some implementations, voltages having different levels may be provided to special word lines, programmed with the same threshold voltage distribution, of special word lines included in a cell block. For example, voltages having different levels may be applied to the common dummy line CDUM1 disposed in an upper portion of the GSL region and the common dummy line CDUM0 disposed in a lower portion of the GSL region.

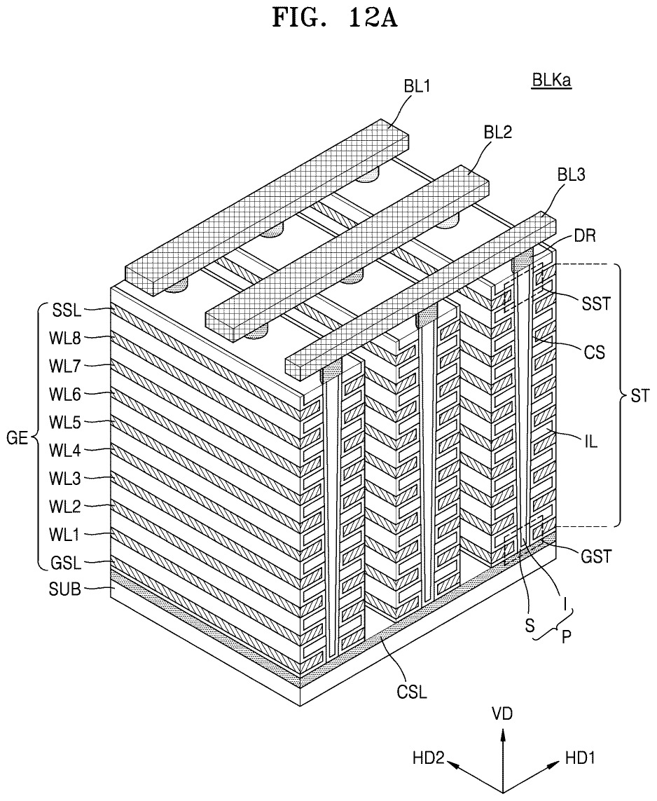

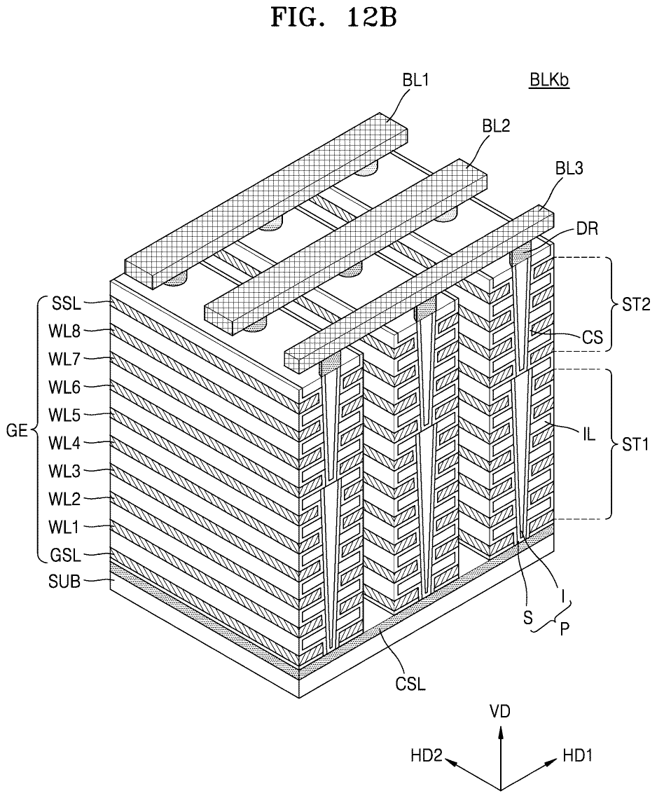

FIGS. 12A and 12B are perspective views illustrating an example of a cell block according to some implementations. In FIG. 12A, a cell block BLKa may correspond to one of the plurality of cell blocks BLK1 to BLKz of FIG. 3. The cell block BLKa may include a memory stack ST which extends in a vertical direction VD, on a substrate SUB. For example, the cell block BLKa may include a single memory stack ST between the substrate SUB and bit lines BL1 to BL3. Common source lines CSL may be disposed in the substrate SUB, insulation layers IL extending in a second horizontal direction HD2 may be sequentially provided in the vertical direction VD, on a region of the substrate SUB between two adjacent common source lines CSL, and the insulation layers IL may be apart from each other by a certain distance in the vertical direction VD. A plurality of pillars P passing through the insulation layers IL in the vertical direction VD may be provided on a region of the substrate SUB between two adjacent common source lines CSL. A surface layer S of each of the pillars P may include a silicon material having a first type and may function as a channel region. Also, an inner layer I of each pillar P may include an air gap or an insulating material such as silicon oxide.

A charge storage layer CS may be provided along the insulation layers IL, the pillars P, and an exposed surface of the substrate SUB, in a region between two adjacent common source lines CSL. The charge storage layer CS may include a gate insulation layer, a charge trap layer, and a blocking insulation layer. For example, the charge storage layer CS may have an oxide-nitride-oxide (ONO) structure. Also, a gate electrode GE such as selection lines GSL and SSL and word lines WL1 to WL8 may be provided on an exposed surface of the charge storage layer CS, in a region between two adjacent common source lines CSL. Drains DR may be respectively provided on the plurality of pillars P. Bit lines BL1 to BL3, which extend in a first horizontal direction HD1 and are apart from one another by a certain distance in a second horizontal direction HD2, may be provided on the drains DR.

In FIG. 12B, a cell block BLKb may correspond to one of the plurality of cell blocks BLK1 to BLKz of FIG. 3. Also, the cell block BLKb may correspond to a modification example of the cell block BLKa of FIG. 12A, and descriptions given above with reference to FIG. 12A may be applied to some implementations. The cell block BLKb may include a first memory stack ST1 and a second memory stack ST2, which are stacked on a substrate SUB in a vertical direction VD. For example, the cell block BLKb may include two memory stacks (i.e., the first and second memory stacks ST1 and ST2) between the substrate SUB and bit lines BL1 to BL3, and thus, may have a multi-stack structure (for example, a 2-stack structure). In this case, lengths of the first and second memory stacks ST1 and ST2 in a vertical direction may differ. However, the present disclosure is not limited thereto, and according to some implementations, the cell block BLKb may include three or more memory stacks between the substrate SUB and the bit lines BL1 to BL3.

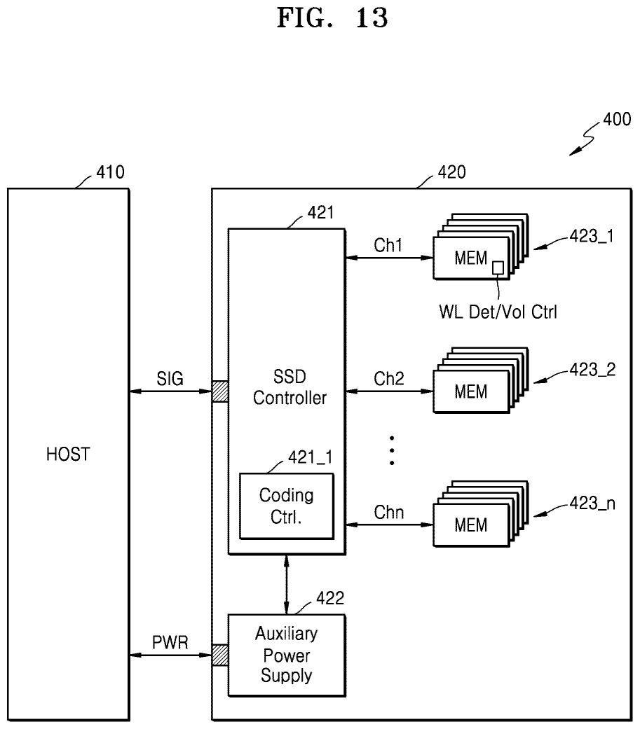

FIG. 13 is a block diagram illustrating an example of a storage device to which a memory device is applied according to some implementations. For example, the storage device of FIG. 13 may be a solid state drive (SSD) device, and a system of FIG. 13 may be referred to as an SSD system 400.

In FIG. 13, the SSD system 400 may include a host 410 and an SSD device 420. The SSD device 420 may transmit and receive a signal to and from a host 410 through a signal connector and may be supplied with power through a power connector. The SSD device 420 may include an SSD controller 421, an auxiliary power supply 422, and memory devices 423_1 to 423_n. The memory devices 423_1 to 423_n may each be a vertical stack-type NAND flash memory device. In this case, the SSD device 420 may be implemented by using some implementations described above with reference to FIGS. 1 to 12. That is, each of the memory devices 423_1 to 423_n may include a plurality of cell blocks, and each of the cell blocks may include a GSL region including a plurality of ground selection lines.

The SSD controller 421 may include a coding controller 421_1, and the coding controller 421_1 may control an operation of programming threshold voltages of ground selection lines of the GSL region included in the memory devices 423_1 to 423_n according to some implementations. For example, control information associated with coding of the GSL region may be stored in the SSD controller 421 or the memory devices 423_1 to 423_n, and the coding controller 421_1 may program each of the ground selection lines with a certain threshold voltage, based on the control information.

Furthermore, according to some implementations, each of the memory devices 423_1 to 423_n may include a word line position determiner and a voltage level controller. For example, in a program operation on each of the memory devices 423_1 to 423_n, when a main word line corresponding to an upper word line of a cell block is programmed, at least one ground selection line of a GSL region of the cell block may be cut off, and a voltage having a certain level may be applied to a channel corresponding to the GSL region. On the other hand, in the program operation on each of the memory devices 423_1 to 423_n, when a main word line corresponding to a lower word line of the cell block is programmed, at least one special word line disposed in a lower portion of the GSL region of the cell block may be cut off, and for example, the program operation may be performed after one or more common ground selection lines are cut off.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array including a plurality of cell blocks, each of the plurality of cell blocks including a plurality of cell strings; and
a control logic circuit configured to control a program operation of the memory cell array,
wherein each of the plurality of cell blocks comprises:
a plurality of main word lines arranged vertically and configured to be programmed with data,
a ground selection line (GSL) region including a plurality of ground selection lines configured to be electrically separated on the plurality of cell strings, and
at least one common GSL disposed in common on the plurality of cell strings, and
wherein the control logic circuit is configured to perform a control operation to:
cut off at least one ground selection line of the plurality of ground selection lines included in the GSL region based on upper word lines of the plurality of main word lines being programmed, and
cut off the at least one common GSL based on lower word lines of the plurality of main word lines being programmed.

2. The memory device of claim 1, wherein, in each of the plurality of cell blocks, the lower word lines correspond to two or more main word lines that are disposed in a lower portion of the plurality of main word lines.

3. The memory device of claim 1,
wherein the plurality of cell blocks includes a first cell block and a second cell block,
wherein a number of main word lines of the first cell block is greater than a number of main word lines of the second cell block,
wherein the lower word lines comprise main word lines disposed in a lower portion of the plurality of main word lines in each of the first cell block and the second cell block, and
wherein a number of the lower word lines of the first cell block is greater than a number of the lower word lines of the second cell block.

4. The memory device of claim 1,
wherein the plurality of ground selection lines of the GSL region comprise at least one first dummy line disposed adjacent to the plurality of main word lines and at least one second dummy line disposed adjacent to the at least one common GSL, and
wherein the at least one first dummy line and the at least one second dummy line are configured to be programmed to have one threshold voltage distribution.

5. The memory device of claim 4, wherein the control logic circuit is configured to perform the control operation to cut off the at least one first dummy line in the GSL region based on the upper word lines being programmed.

6. The memory device of claim 5, wherein the control logic circuit is configured to perform the control operation to turn on the at least one common GSL and the plurality of ground selection lines disposed under the at least one first dummy line in the GSL region to allow a common source voltage to be applied to a channel corresponding to the GSL region.

7. The memory device of claim 4, wherein the control logic circuit is configured to, based on the upper word lines being programmed, perform the control operation to cut off at least one first ground selection line of a coding region between the at least one first dummy line and the at least one second dummy line.

8. The memory device of claim 7,
wherein a channel corresponding to a second ground selection line disposed above the first ground selection line in the GSL region is configured to be a floated channel based on the first ground selection line of the coding region being cut off, and
wherein the control logic circuit is configured to perform a another control operation so that a voltage having a level set based on a threshold voltage distribution of the second ground selection line is provided to the second ground selection line to adjust a potential of the floated channel, and so that a third ground selection line and the at least one common GSL are turned on to allow a common source voltage to be applied to a channel corresponding to the third ground selection line disposed under the first ground selection line.

9. The memory device of claim 1,
wherein a channel corresponding to the GSL region is configured to be a floated channel based on the lower word lines being programmed and based on the at least one common GSL being cut off, and
wherein the control logic circuit is configured to perform a control operation so that voltages having a level set based on a threshold voltage distribution of the plurality of ground selection lines of the GSL region are provided to the plurality of ground selection lines of the GSL region to adjust a potential of the floated channel.

10. The memory device of claim 1,
wherein each of the plurality of cell blocks comprises a first common dummy line disposed in an upper portion of the GSL region and a second common dummy line disposed in a lower portion of the GSL region,
wherein the control logic circuit is configured to program the first common dummy line and the second common dummy line with a same threshold voltage, and
wherein the control logic circuit is configured to apply voltages having different levels to the first common dummy line and the second common dummy line based on the upper word lines being programmed and based on the at least one ground selection line included in the GSL region being cut off.

11. An operating method of a memory device, the memory device including a cell block having a plurality of cell strings and including a first number of main word lines arranged vertically and configured to be programmed with data, a ground selection line (GSL) region including a plurality of ground selection lines configured to be electrically separated on the plurality of cell strings, and at least one common GSL disposed in common on the plurality of cell strings,
the operating method comprising:
receiving a first program command;
in response to the first program command, cutting off the at least one common GSL in a program process of a first main word line, the first main word line being included in a second number of main word lines disposed in a lower portion among the first number of main word lines, the first number of main word lines being greater than 1 and greater than the second number of main word lines;
receiving a second program command; and
in response to the second program command, cutting off at least one ground selection line included in the GSL region in a program process of a second main word line, the second main word line being disposed above the second number of main word lines.

12. The operating method of claim 11,
wherein the plurality of ground selection lines of the GSL region comprise at least one first dummy line disposed adjacent to the main word lines and at least one second dummy line disposed adjacent to the common GSL, and
wherein the at least one first dummy line and the at least one second dummy line are programmed to have one threshold voltage distribution.

13. The operating method of claim 12, comprising cutting off the at least one first dummy line in the GSL region in response to the second program command.

14. The operating method of claim 13, comprising:
in response to the second program command, turning on the at least one common GSL and ground selection lines disposed under the at least one first dummy line in the GSL region to apply a common source voltage to a channel corresponding to the GSL region.

15. The operating method of claim 12, comprising:
in response to the second program command, cutting off at least one ground selection line among the plurality of ground selection lines of a coding region between the at least one first dummy line and the at least one second dummy line in the GSL region.

16. The operating method of claim 11, comprising:
in response to the first program command, floating a channel corresponding to the GSL region as a floated channel based on the at least one common GSL being cut off; and
providing voltages, having a level set based on a threshold voltage distribution of the plurality of ground selection lines of the GSL region, to the plurality of ground selection lines of the GSL region to adjust a potential of the floated channel.

17. A memory system comprising:
a memory controller configured to communicate with a host and output a command and an address for controlling a memory operation, based on a request of the host; and
a memory device including a plurality of cell blocks, the memory device being configured to perform a program operation in response to the command and the address from the memory controller,
wherein each of the plurality of cell blocks comprises:
a plurality of main word lines arranged vertically and configured to be programmed with data,
a ground selection line (GSL) region including a plurality of ground selection lines configured to be electrically separated on a plurality of cell strings, and
a plurality of special word lines disposed under the GSL region, and
wherein the memory device is configured to perform a control operation to:
cut off at least one ground selection line among the plurality of ground selection lines included in the GSL region based on upper word lines of the plurality of main word lines being programmed, and
cut off the at least one of the plurality of special word lines based on lower word lines of the plurality of main word lines being programmed.

18. The memory system of claim 17, wherein the lower word lines include a number of main word lines disposed in a lower portion among the plurality of main word lines in each of the plurality of cell blocks.

19. The memory system of claim 17,
wherein the plurality of special word lines comprise at least one common GSL in common on the plurality of cell strings, and
wherein the at least one common GSL of the plurality of special word lines is configured to be cut off based on the lower word lines being programmed.

20. The memory system of claim 17, wherein the memory device is configured to, based on the upper word lines being programmed, provide a turn-on voltage to the plurality of special word lines and at least a portion of the plurality of ground selection lines of the GSL region to apply a common source voltage to a channel corresponding to the GSL region.
